(19) United States
(12) Patent Application Publication
(10) Pub. No.: US 2005/0045992 A1
(43) Pub. Date: Mar. 3, 2005

(54) Bipolar/thin film SOI CMOS structure and method of making same

(76) Inventor: Alfred P. Turley, Ellicott City, MD (US)

Correspondence Address: BIRCH STEWART KOLASCH & BIRCH, PO BOX 747, FALLS CHURCH, VA, 22040-0747, US

(21) Appl. No.: 10/648,206

(22) Filed: Aug. 27, 2003

(51) Int. Cl. H01L 29/00

(52) U.S. Cl. 257/552

(57) ABSTRACT

A semiconductor wafer structure which includes at least one bipolar transistor defined in the semiconductor wafer structure as well as at least one CMOS transistor device also defined in the semiconductor wafer structure. The CMOS transistor device is comprised of a thin film of semiconductor on an insulating layer with each transistor of the CMOS transistor device being defined in the thin film. The bipolar transistor has a plurality of semiconductor layers of predetermined conductivities, without any of the semiconductor layers of the bipolar transistor extending into the area occupied by the CMOS transistor device. A method of fabricating the structure is also disclosed.

### BACKGROUND OF THE INVENTION

1. Field of the Invention

The invention in general relates to wafer scale technology and more particularly to an improved silicon germanium bipolar transistor/CMOS structure.

2. Description of Related Art

Silicon germanium bipolar heterojunction transistors have been developed and compared to conventional silicon bipolar transistors are faster, more energy efficient and are cost competitive, if not cheaper than the silicon variety.

These silicon germanium bipolar heterojunction transistors are used not only in such applications as ASICs (application specific integrated circuits) but are used in other fields including communications systems and military radars. These devices provide much improved performance at high frequencies and at reduced temperatures and reduced power consumption.

The silicon germanium bipolar heterojunction transistors maintain compatibility with CMOS (complementary metal-oxide semiconductor) technology) and are fabricated on the same semiconductor wafer as the CMOS circuitry. The bipolar transistors may, for example, operate as amplifiers, while the CMOS circuitry may operate as switches. When used in microwave applications, present day silicon germanium bipolar heterojunction transistor/CMOS circuitry tends to be objectionably lossy due to low resistivity silicon material in which the transistors are fabricated. Further, the circuitry is slowed down and cannot fully isolate the RF signals when operating in a switching mode due to p-n junction capacitance.

The present invention obviates these drawbacks of currently available device fabrication technology.

### SUMMARY OF THE INVENTION

A semiconductor wafer structure is provided which includes at least one bipolar transistor defined in the semiconductor wafer structure and at least one CMOS transistor device also defined in the semiconductor wafer structure. The CMOS transistor device is comprised of a thin film of semiconductor on an insulating layer with each transistor of the CMOS transistor device being defined in the thin film and including spaced apart source and drain regions and an intermediate channel region, each region being the thickness of the thin film. A respective gate is disposed on an oxide film on the channel region of each transistor of the CMOS transistor device. The structure includes a plurality of electrodes connected to selected elements of the bipolar transistor and CMOS transistor device.

A method of making the semiconductor wafer structure includes the steps of fabricating the CMOS transistor device with source, drain and channel regions of each transistor of the CMOS transistor device being contained within a thin film of semiconductor material, and fabricating the bipolar transistor with a plurality of semiconductor layers of predetermined conductivities, without any of the semiconductor layers of the bipolar transistor extending into the area occupied by the CMOS transistor device.

Further scope of applicability of the present invention will become apparent from the detailed description provided hereinafter. It should be understood, however, that the detailed description and specific example, while disclosing the preferred embodiment of the invention, is provided by way of illustration only, since various changes and modifications within the spirit and scope of the invention will become apparent to those skilled in the art, from the detailed description.

### BRIEF DESCRIPTION OF THE DRAWINGS

The present invention will become more fully understood from the detailed description provided hereinafter and the accompanying drawings, which are not necessarily to scale, and are given by way of illustration only, and wherein:

FIGS. 1 and 2 are cross-sectional simplified views of prior art silicon germanium bipolar heterojunction transistor/CMOS devices.

FIG. 3 is a cross-sectional simplified view of a device in accordance with one embodiment of the invention.

FIGS. 4A to 4M are views of the fabrication process for fabricating the device of FIG. 3.

### DESCRIPTION OF THE PREFERRED EMBODIMENT

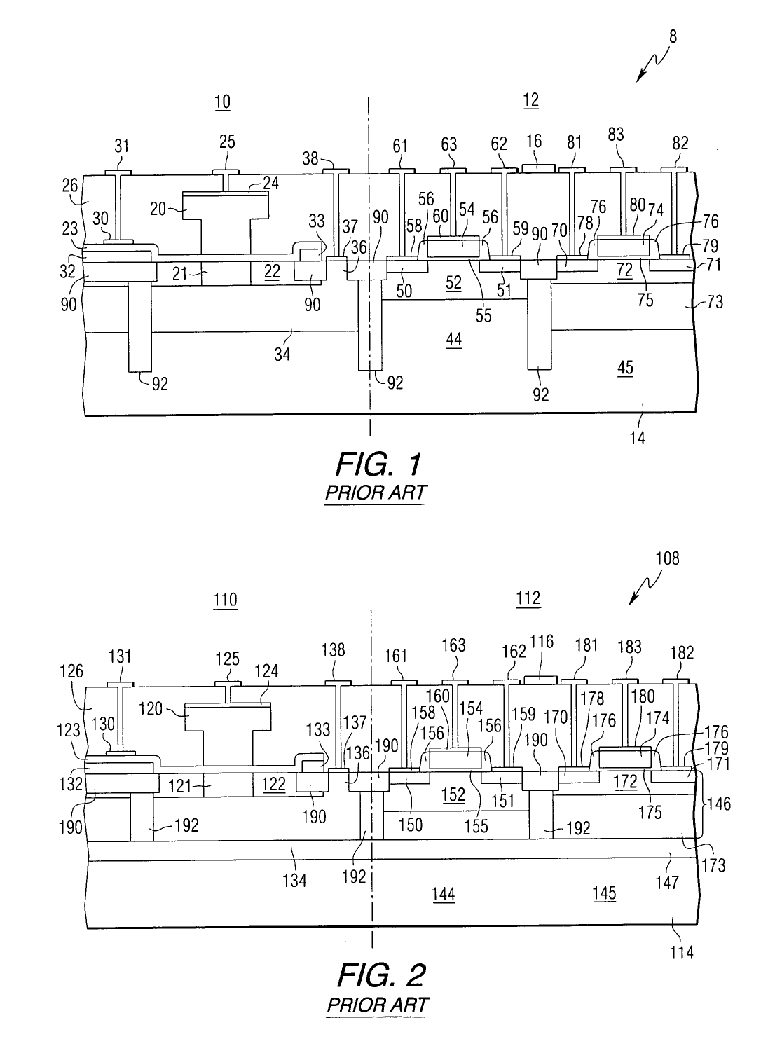

FIG. 1 illustrates a prior art silicon-based wafer structure arrangement 8 wherein a silicon germanium bipolar heterojunction transistor 10 and a CMOS transistor device 12 are formed on the same silicon wafer substrate 14. For convenience, in the Figures, the bipolar transistor and CMOS device are shown adjacent one another. In actuality the wafer arrangement may contain a multitude of such elements, and not necessarily adjacent, along with other circuit components, including signal transmission lines, one of which, 16, is illustrated.

The bipolar transistor 10 includes an emitter 20, a collector 21 formed in epitaxially grown collector layer 22, and a base 23 interposed between the emitter and collector. The emitter 20 and collector 21 are of one conductivity type for example, n-type, while the base 23 is of an opposite conductivity p-type. For superior operation, and high speed performance, the base 23 is of a silicon germanium composition, generally 90% silicon and 10% germanium. The substrate 14 is of a relatively low resistivity, for example, 8 ohm-cm, p-type silicon.

Deposited on top of the emitter 20 is an electrically conducting layer, such as platinum, for forming a plurality of contacts, into the plane of the Fig. One such contact, contact 24, is illustrated as being electrically connected to an electrode 25, such as aluminum. This electrode 25, as well as all of the electrodes to be described, extends through a protective oxide layer 26 (actually composed of multiple depositions of oxide layers) to enable connection to other circuit components, including power supplies.

Base 23 includes contact(s) 30 for connection of electrode 31. Base 23 is extremely thin, for example on the order of 500 to 1000 Å and its edges are built up on respective polysilicon extrinsic layers 32 and 33. Thus the fragile base 23 is reinforced and protected during the fabrication process in which the oxide 26 is etched down to contact(s) 30 for deposition of electrode 31.

In order to make electrical connection with collector 21, collector 21 is formed on a highly doped n-type low resistivity conducting layer 34. A collector sinker 36 is formed on top of the low resistivity layer 34 and includes contact(s) 37 for connection to electrode 38.

The CMOS transistor device 12 is comprised of adjacent NMOS and PMOS transistors 44 and 45. NMOS transistor 44 includes an n⁺ source 50, an n⁺ drain 51 and an intermediate channel region, p-well 52, for conduction of majority carriers. Conduction is governed by polysilicon gate 54, disposed over oxide layer 55, which also extends up the side walls of gate 54, forming spacers 56. Contacts 58, 59 and 60, on top of the respective source, drain and gate are connected to respective electrodes 61, 62 and 63.

PMOS transistor 45 includes a p⁺ source 70, a p⁺ drain 71 and an intermediate channel region, n-well 72, for conduction of majority carriers. The n-well 72 is contiguous a low resistivity layer 73. This low resistivity layer 73 serves as an isolation layer and prevents any depletion layer from interfering with a neighboring device. Conduction of the transistor is governed by polysilicon gate 74, disposed over oxide layer 75, which also extends up the side walls of gate 74, forming spacers 76. Contacts 78, 79 and 80, on top of the respective source, drain and gate elements are connected to respective electrodes 81, 82 and 83.

In the fabrication process of the structure 8, the low resistivity layer 73 of PMOS 45 is formed as part of the same processing step as the low resistivity layer 34 of bipolar transistor 10. In addition, layer 22 is deposited across both the bipolar transistor 10 and CMOS transistor device 12 during fabrication, to accommodate not only the collector 21 of bipolar transistor 10, but also the p-well 52, n-well 72 and source and drain regions of CMOS transistor 12.

Structure 8 is fabricated with a plurality of isolation trenches of an oxide or other insulating material and includes shallow isolation trenches 90 as well as deep isolation trenches 92. In addition to providing an insulating layer between polysilicon extrinsic layer 32 and substrate 14, the isolation trenches allow for a greater packing density of transistor devices without mutual interference problems.

If structure 8 is utilized in high frequency applications, such as in various radar systems, the presence of low resistivity silicon (8-ohm cm) and the relatively thick wells of the CMOS transistor device 12, leads to undesirable transmission line losses. In addition, with the CMOS transistor device 12 used as a high frequency switch, a significant amount of capacitance exists between the source/drain regions and the underlying wells. This high capacitance has the effect of degrading switch operation by diminishing the CMOS's ability to block RF signals, when in an off state.

The prior art arrangement of FIG. 2 provides somewhat better high frequency performance than that of FIG. 1. The transistor structure 108 of FIG. 2 includes the bipolar transistor 110 on the same wafer substrate 114 as CMOS transistor device 112, as in FIG. 1.

The bipolar transistor 110 includes an emitter 120, a collector 121, formed in epitaxially grown collector layer 122, and a base 123 interposed between the emitter and collector. The emitter 120 and collector 121 are of one conductivity type for example, n-type, while the base 123 is of an opposite conductivity p-type. For superior operation, and high frequency performance, the base 123 is of a silicon germanium composition, as in FIG. 1. The substrate 114 is p-type silicon of a selected low or high resistivity.

Deposited on top of the emitter 120 is an electrically conducting layer, such as platinum, for forming a plurality of contacts, into the plane of the Fig. One such contact, contact 124, is illustrated as being electrically connected to an electrode 125, such as aluminum. This electrode 125, as well as all of the electrodes in FIG. 2, extends through a protective multiple deposition oxide layer 126 to enable connection to other circuit components, including power supplies.

Base 123 includes contact(s) 130 for connection of electrode 131. Base 123 has its edges are built up on respective polysilicon extrinsic layers 132 and 133 for the purpose stated with respect to FIG. 1.

In order to make electrical connection with collector 121, collector 121 is formed on a highly doped n-type low resistivity conducting layer 134. A collector sinker 136 is formed on top of the low resistivity layer 134 and includes contact(s) 137 for connection to electrode 138.

The CMOS transistor device 112 is comprised of adjacent NMOS and PMOS transistors 144 and 145. As opposed to being defined in the substrate, as in FIG. 1, the CMOS transistor device 112 is defined in a silicon layer arrangement 146, of several microns thickness, deposited on a buried oxide insulating layer 147 which insulates the CMOS transistor device 112 from substrate 114. This silicon layer arrangement 146 is formed in the same processing steps which form the low resistivity layer 134 and collector layer 122, of bipolar transistor 110.

NMOS transistor 144 includes an n⁺ source 150, an n⁺ drain 151 and an intermediate channel region, p-well 152, for conduction of majority carriers. Conduction is governed by polysilicon gate 154, disposed over oxide layer 155, which also extends up the side walls of gate 154, forming spacers 156. Contacts 158, 159 and 160, on top of the respective source, drain and gate are connected to respective electrodes 161, 162 and 163.

PMOS transistor 145 includes a p⁺ source 170, a p⁺ drain 171 and an intermediate channel region, n-well 172, for conduction of majority carriers. The n-well 172 is contiguous the low resistivity layer 173, as in FIG. 1. Conduction of the transistor is governed by polysilicon gate 174, disposed over oxide layer 175, which also extends up the side walls of gate 174, forming spacers 176. Contacts 178, 179 and 180, on top of the respective source, drain and gate elements are connected to respective electrodes 181, 182 and 183.

In the fabrication process of the structure 108, the low resistivity layer 173 of PMOS 145 is formed as part of the same processing step as the low resistivity layer 134 of bipolar transistor 110. In addition, layer 122 is deposited across both the bipolar transistor 110 and CMOS transistor device 112 during fabrication, to accommodate not only the collector 121 of bipolar transistor 110, but also the p-well 152 and n-well 172 of CMOS transistor 112, as well as the source and drain regions of the CMOS transistors.

Structure 108 also includes the plurality of isolation trenches in the form of shallow isolation trenches 190 as well as deep isolation trenches 192.

The structure of FIG. 2 provides improved isolation between devices, however, there are several drawbacks which limit microwave performance. For example, even if a high resistivity substrate 114 is utilized, the 2 to 3 micron layer 146 above the buried insulator 147 interposes a low resistivity layer between the transmission line(s) 116 and the high resistivity substrate 114. This degrades the performance of the transmission lines, as well as other deposited components such as spiral inductors. In addition, the significant amount of capacitance existing between the source/drain regions and the underlying wells still degrades CMOS operation in the switching mode.

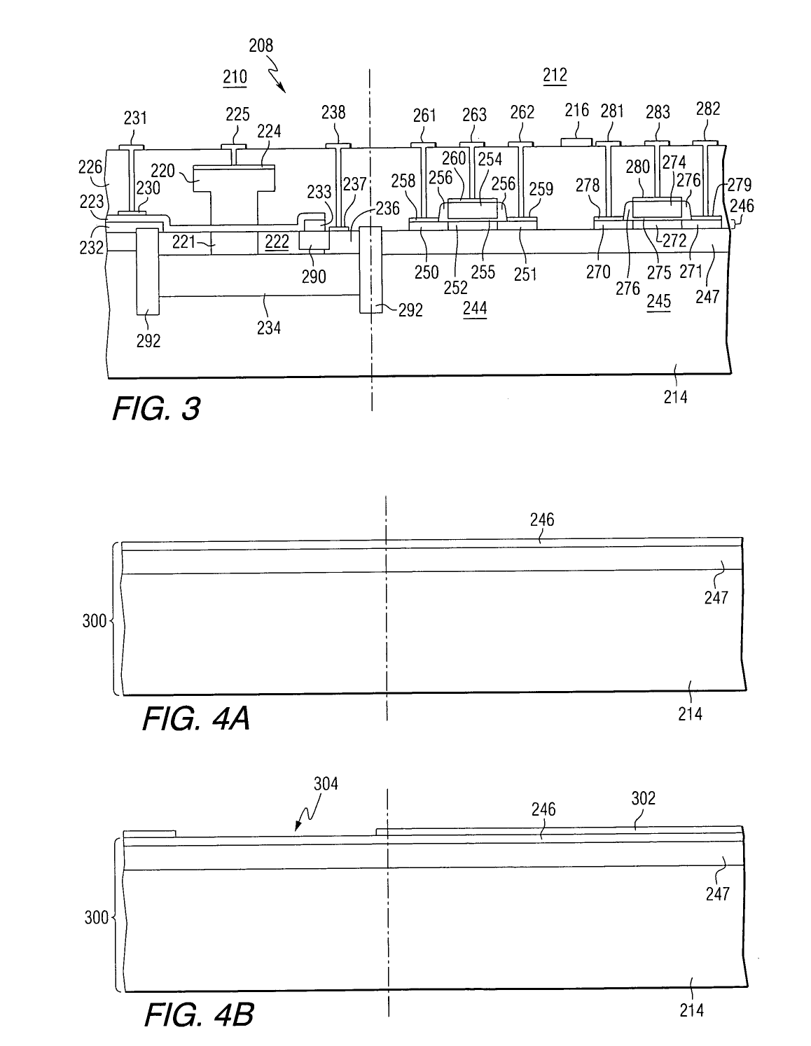

The present invention obviates the drawbacks associated with prior art bipolar/CMOS transistor devices, and to that end reference is made to FIG. 3, illustrating one embodiment of the invention.

The transistor structure 208 of FIG. 3 includes at least one bipolar transistor 210 on the same wafer substrate 214 as at least one CMOS transistor device 112, as in FIGS. 1 and 2.

The structure of bipolar transistor 210 is similar to those in FIGS. 1 and 2 and includes an emitter 220, a collector 221, formed in epitaxially grown collector layer 222, and a base 223 interposed between the emitter and collector. The emitter 220 and collector 221 are of one conductivity type for example, n-type, while the base 223 is of an opposite conductivity p-type. For superior operation, and high frequency performance, the base 223 is of a silicon germanium composition, as in FIGS. 1 and 2. The substrate 214 is p-type silicon of a high resistivity, for example equal to or greater than 1,500 ohm-cm.

Deposited on top of the emitter 220 is an electrically conducting layer for forming a plurality of contacts, into the plane of the Fig. One such contact, contact 224, is illustrated as being electrically connected to an electrode 225, such as aluminum. This electrode 225, as well as all of the electrodes in FIG. 3, extends through a protective multiple deposition oxide layer 226 to enable connection to other circuit components, including power supplies.

Base 223 includes contact(s) 230 for connection of electrode 231. Base 223 has its edges built up on respective polysilicon extrinsic layers 232 and 233 for the purpose stated with respect to FIG. 1.

In order to make electrical connection with collector 221, collector 221 is formed on a highly doped n-type low resistivity conducting layer 234. A collector sinker 236 is formed on top of the low resistivity layer 234 and includes contact(s) 237 for connection to electrode 238.

The CMOS transistor device 212 is comprised of adjacent NMOS and PMOS transistors 244 and 245. As opposed to being defined in the substrate, as in FIG. 1, or in the relatively thick layer 146 of FIG. 2, the CMOS transistor device 212 is defined in an SOI (semiconductor on insulator) structure comprised of thin silicon layer 246 deposited on a buried oxide insulating layer 247 which insulates the CMOS transistor device 212 from substrate 214. The silicon layer 246 is no more than around 3000 Å (Angstroms) and is preferably around 1000 Å. With this construction there are no regions of low resistivity silicon material interposed between metal lines, such as transmission line 216, and the high resistivity substrate 214.

NMOS transistor 244 includes an n⁺ source 250, an n⁺ drain 251 and an intermediate p channel region 252, for conduction of majority carriers and all in the same essentially planar layer of silicon. That is, source, drain and channel regions have the same thickness as the thin film silicon layer 246. Conduction is governed by polysilicon gate 254, disposed over oxide layer 255, which also extends up the side walls of gate 254 forming spacers 256. Contacts 258, 259 and 260, on top of the respective source, drain and gate are connected to respective electrodes 261, 262 and 263.

PMOS transistor 245 includes a p⁺ source 270, a p⁺ drain 271 and an intermediate n channel region 272, (all of the same thickness as the thin film silicon layer 246) for conduction of majority carriers. Conduction of the transistor is governed by polysilicon gate 274, disposed over oxide layer 275, which also extends up the side walls of gate 274 forming spacers 276. Contacts 278, 279 and 280, on top of the respective source, drain and gate elements are connected to respective electrodes 281, 282 and 283.

Structure 208 also includes the plurality of isolation trenches in the form of shallow isolation trenches 290 as well as deep isolation trenches 292.

Although alternate conductivity types are illustrated for the adjacent source, channel and drain regions of NMOS transistor 244 and PMOS transistor 245, the doping could be such as to be of the same conductivity type, with alternately different dopings, thus forming a ppp and nnn CMOS transistor device, as illustrated in U.S. Pat. No. 5,969,385, which is hereby incorporated by reference.

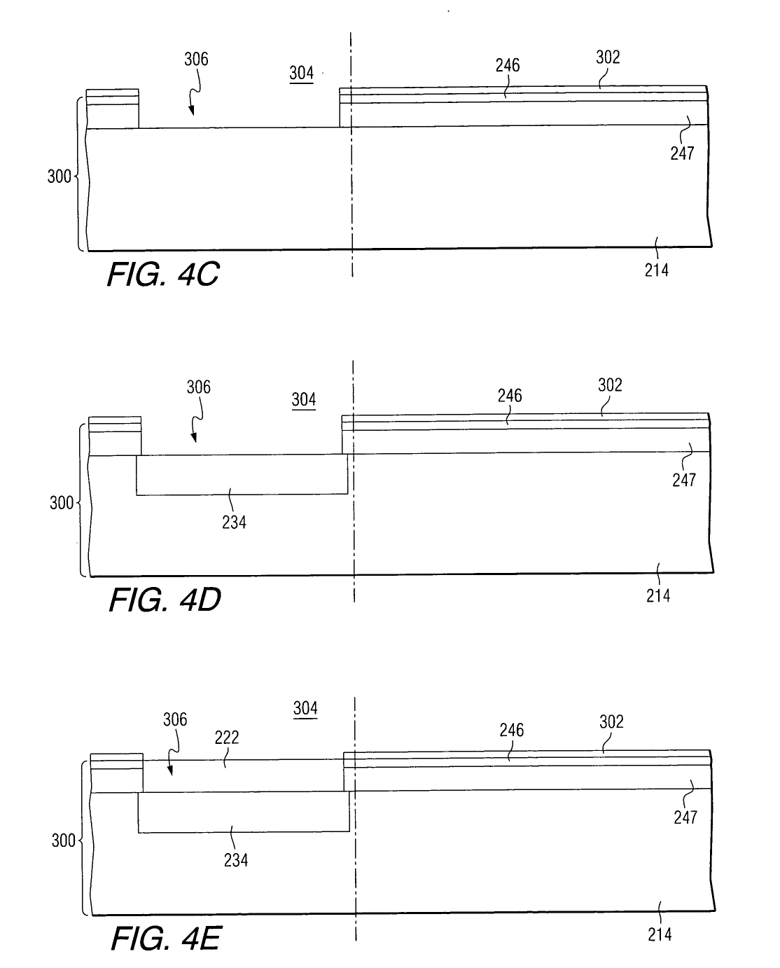

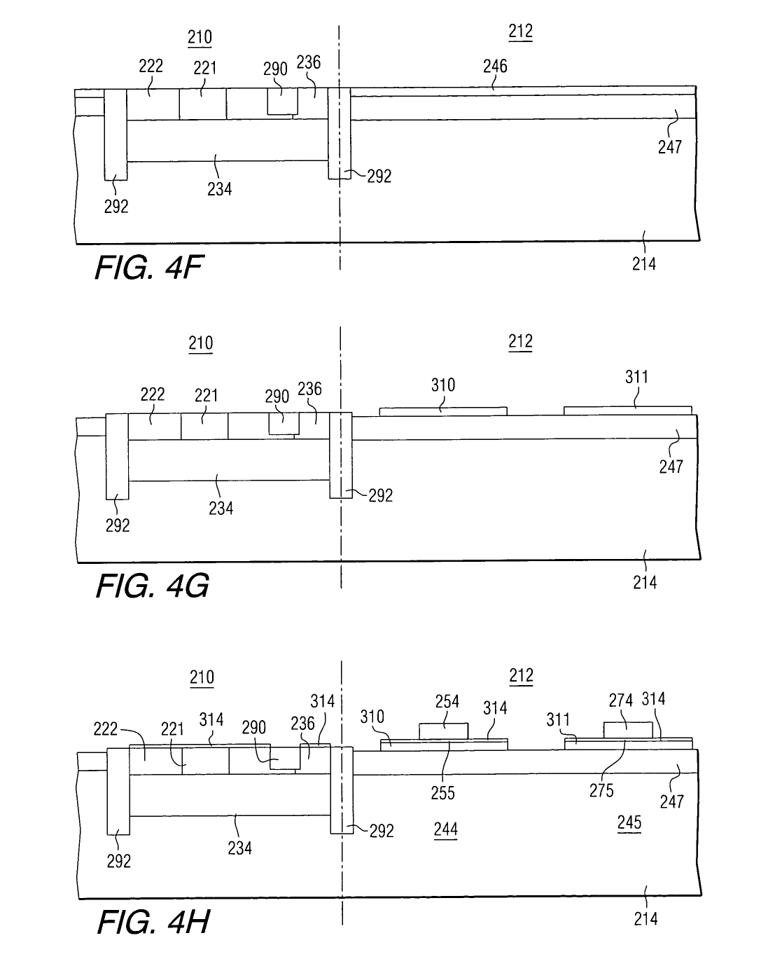

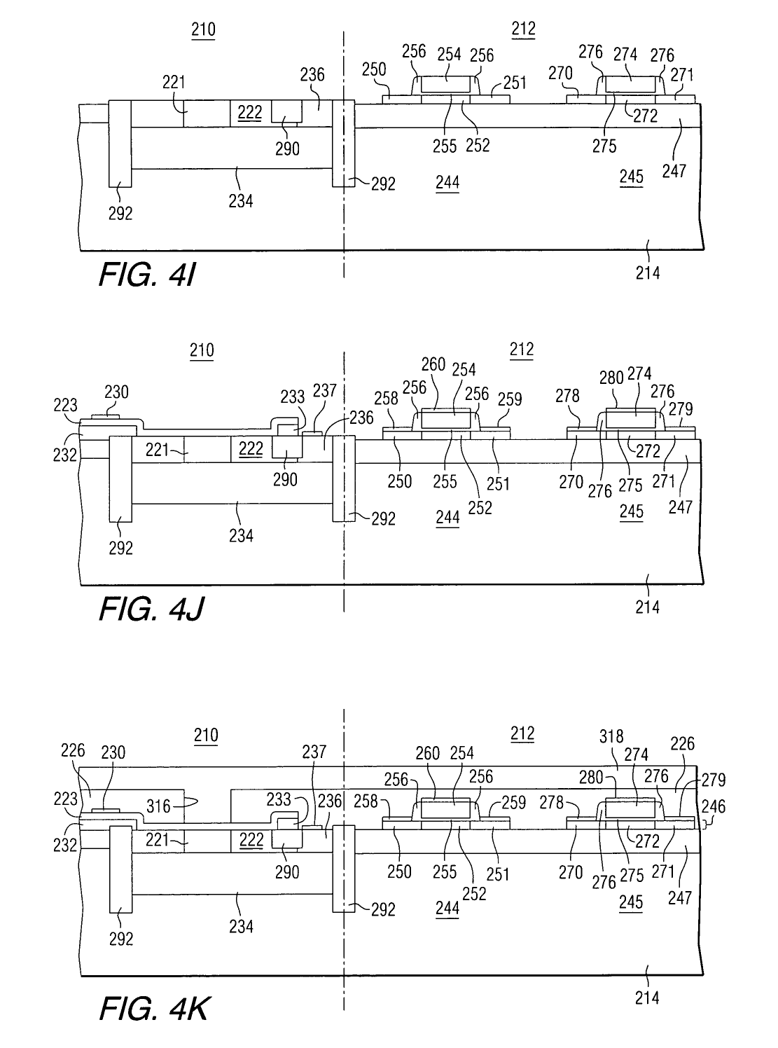

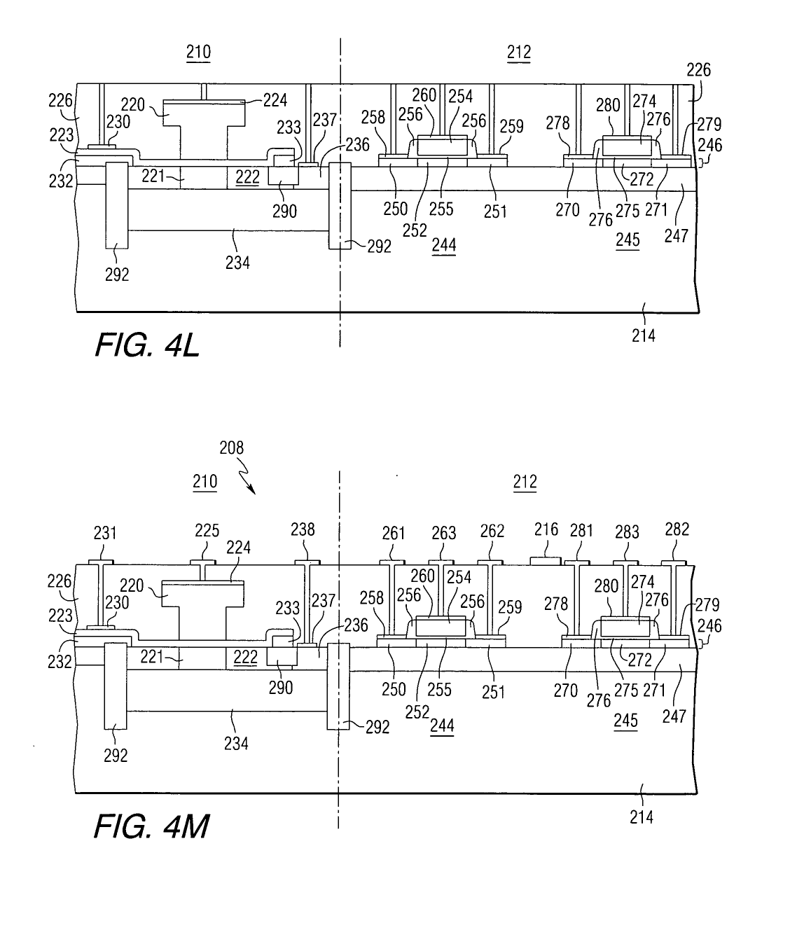

The referenced patent however does not illustrate a CMOS transistor device fabricated on the same wafer as a bipolar transistor; a preferred method of fabrication of such combination is illustrated in FIGS. 4A to 4M, in which components previously described with respect to FIG. 3 have been given the same reference numerals. In the fabrication process to be described, the selective removal or selective deposition of a material may be carried out by a number of steps, well-known in the silicon wafer processing field. These well-known steps include, for example, diffusion, ion implantation, photoresist masking, various methods of etching, and subsequent resist removal, and accordingly will not be discussed in detail.

The bipolar/CMOS structure is fabricated on the SOI wafer structure 300 illustrated in FIG. 4A. This SOI wafer structure may be commercially purchased or may be assembled by providing a high resistivity substrate onto which is grown the oxide insulator and thin film of silicon.

A silicon oxide 302 is deposited on the silicon surface of the SOI wafer structure 300 and a portion is subsequently removed in the region 304 of the bipolar transistor to be formed, as illustrated in FIG. 4B. In FIG. 4C, the thin film of silicon 246 and insulating layer 247 of SOI wafer structure 300 are etched away to form a well 306, and expose the surface of the high resistivity substrate 214, at the bottom of the well.

In FIG. 4D the low resistivity layer 234 has been implanted and diffused into the silicon substrate 214. Thereafter, and as indicated in FIG. 4E, the epitaxial collector layer 222 is selectively formed in the well 306. This may be accomplished by deposition of layer 222 only in the well 306 or by a blanket epitaxial growth in the well 306, as well as over oxide 302, with subsequent polishing or etching to remove it from areas other than well 306.

It is to be noted that even though the bipolar transistor and CMOS device are fabricated on the same wafer, the low resistivity layer 234 and collector layer 222 are confined to only the bipolar transistor region 304, do not extend to the area occupied by the CMOS transistor device and do not form any part of the CMOS transistor device, as is the case of the prior art structures of FIGS. 2 and 3.

The results of several steps are illustrated in FIG. 4F and include the implantation of collector 221 into layer 222 and the formation of trenches 290 and 292 by etching and filling with an insulator. Subsequent removal of excess trench material may be by chemical mechanical polishing which also removes the protective oxide 302 (FIG. 4E) over silicon layer 246, such that the respective surfaces of collector 221, collector layer 222 and silicon layer 246 are coplanar. In addition, the collector sinker 236 is formed by ion implantation into layer 222.

In FIG. 4G silicon layer 246 (FIG. 4F) of the SOI wafer structure 300 is etched to form individual silicon islands 310 and 311, the precursor to the CMOS transistors. The next few fabrication steps, illustrated in FIG. 4H include the formation of the gate oxide layers 255 and 275. This is accomplished by thermally growing at high temperatures, a silicon dioxide layer 314 over all of the exposed silicon. Gates 254 and 274 result from a blanket deposition, and subsequent selective removal, of a polysilicon layer.

An oxide layer is then blanket deposited and thereafter a reactive ion etch, without any masking, removes all of the oxide on the horizontal surfaces, resulting in the structure of FIG. 4I, wherein only the oxide spacers 256 and 276 remain on the vertical surfaces of gates 254 and 274. Masking and ion implantation steps form the respective source and drain regions 250, 270 and 251, 271.

Polysilicon extrinsic layers 232 and 233 are deposited and patterned for receiving the epitaxial silicon or silicon germanium base 223 of the bipolar transistor, as indicated in FIG. 4J. After a protective oxide layer is deposited on the base 223 and collector sinker 236, leaving exposed areas where contacts are to be formed, a blanket deposition of titanium is made over the wafer. Thereafter, the structure is subjected to a thermal anneal wherein the titanium reacts with the exposed silicon and polysilicon to form titanium silicide contacts 230, 237, 258-260 and 278-280. A subsequent wet chemical etch removes the titanium from the areas where it hasn't formed the silicide.

In FIG. 4K a portion of the protective oxide layer 226 is deposited and an aperture 316 is etched for the vertical pedestal portion of the emitter. A blanket deposition of polysilicon 318 fills the aperture 316 and covers the surface of the oxide 226. The polysilicon deposition is patterned to remove the polysilicon, except for the top horizontal portion of the emitter, as indicated in FIG. 4L. Titanium silicide emitter contact 224 is formed as previously described, the remainder of oxide layer 226 is deposited and apertures are etched in the oxide layer 226 down to the respective contacts.

A blanket deposition of metallization and subsequent patterning of the metallization on the surface of oxide layer 226 then results in the finished structure illustrated in FIG. 4M. This construction is less susceptible to radiation effects than is prior art structures and the technology described herein can produce high frequency mixed-signal systems on a chip that can dramatically reduce parts count in commercial as well as military systems resulting in improvements in system cost, size and weight.

The foregoing detailed description merely illustrates the principles of the invention. It will thus be appreciated that those skilled in the art will be able to devise various arrangements which, although not explicitly described or shown herein, embody the principles of the invention and are thus within its spirit and scope.

1. A semiconductor wafer structure, comprising:
at least one bipolar transistor defined in said semiconductor wafer structure;
at least one CMOS transistor device defined in said semiconductor wafer structure;
said CMOS transistor device being comprised of a thin film of semiconductor on an insulating layer;
each transistor of said CMOS transistor device being defined in said thin film and including spaced apart source and drain regions and an intermediate channel region, each said region being the thickness of said thin film; and
a respective gate disposed on an oxide film on said channel region of each said CMOS transistor device; and
a plurality of electrodes connected to selected elements of said bipolar transistor and said CMOS transistor device.

2. A wafer structure according to claim 1 wherein:
said bipolar transistor includes a base;
said base being of a silicon-germanium semiconductor material.

3. A wafer structure according to claim 1 wherein:
the thickness of said thin film of semiconductor is no more than 3000 Å.

4. A wafer structure according to claim 3 wherein:
the thickness of said thin film of semiconductor is around 1000 Å.

5. A wafer structure according to claim 1 wherein:
said CMOS transistor device includes first and second MOS transistors each having a source and drain region of a different conductivity type than its channel region.

6. A wafer structure according to claim 1 wherein:
said insulating layer is on a substrate;
said substrate has a relatively high resistivity of around 1500 ohm-cm, or greater.

7. A method of fabricating a semiconductor wafer structure having at least one bipolar transistor, which includes a collector, base and emitter, and at least one CMOS transistor device defined in the same wafer structure, comprising the steps of:
fabricating said CMOS transistor device with source, drain and channel regions of each transistor of said CMOS transistor device being contained within a thin film of semiconductor material;
fabricating said bipolar transistor with a plurality of semiconductor layers of predetermined conductivities, without any of said semiconductor layers of said bipolar transistor, during fabrication, extending into the area occupied by said CMOS transistor device.

8. A method according to claim 7, which includes the steps of:
providing a semiconductor structure having a substrate with a semiconductor on insulator layer arrangement on a surface thereof;
depositing a protective oxide layer over said semiconductor on insulator layer arrangement;
removing a portion of said deposited oxide layer, semiconductor and insulator to form a well down to said surface of said substrate, in the area where said bipolar transistor is to be fabricated;
forming a low resistivity layer in said substrate at the bottom of said well;
selectively forming an epitaxial layer in said well on said low resistivity layer and confined to said bipolar transistor area;
forming a collector within said epitaxial layer;
removing said deposited oxide layer;
selectively removing said semiconductor on said insulator in a pattern so as to define two individual islands of semiconductor;
fabricating said CMOS transistor device utilizing said islands of semiconductor;
fabricating said base and emitter of said bipolar transistor;
establishing electrical contact with elements of said bipolar transistor and said CMOS transistor device.

9. A method according to claim 8, which includes the step of:
selectively forming said epitaxial layer only in said well to the exclusion of other areas of said structure.

10. A method according to claim 8, which includes the steps of:
forming said epitaxial layer over said low resistivity layer and said deposited oxide layer; and
thereafter removing said epitaxial layer formed over said deposited oxide layer.

11. A method according to claim 8, which includes the step of:
providing a semiconductor structure having a substrate with a semiconductor on insulator layer arrangement on a surface thereof, where the the thickness of said semiconductor on said insulator is no more than 3000 Å.

12. A method according to claim 11, which includes the step of:
providing a semiconductor structure having a substrate with a semiconductor on insulator layer arrangement on a surface thereof, where the the thickness of said semiconductor on said insulator is no more than around 1000 Å.
